(19) United States
(12) Patent Application Publication
(10) Pub. No.: US 2023/0387210 A1
(43) Pub. Date: Nov. 30, 2023

(54) SEMICONDUCTOR DEVICES AND METHODS FOR FABRICATION THEREOF

(71) Applicant: TAIWAN SEMICONDUCTOR MANUFACTURING COMPANY, LTD., Hsinchu (TW)

(72) Inventors: Jui-Lin CHANG, Taipei (TW); Tsung-Yu CHIANG, New Taipei (TW); Mi-Hua LIN, Hsinchu (TW); Cing-Yao JHAN, Keelung (TW)

(21) Appl. No.: 17/752,211

(22) Filed: May 24, 2022

(51) Int. Cl. H01L 29/10; H01L 29/78; H01L 29/161; H01L 21/02; H01L 21/311; H01L 21/3115; H01L 21/762; H01L 29/66

(52) U.S. Cl. CPC H01L 29/1054; H01L 29/7851; H01L 29/161; H01L 21/02532; H01L 21/31111; H01L 21/31155; H01L 21/76224; H01L 29/66545; H01L 29/66795

(57) ABSTRACT

Embodiments of the present disclosure provides a solution to address any issues caused by non-uniform channel heights across a substrate. Particularly, an isolation layer is selectively implanted to alter etching rate of the isolation layer around semiconductor fin structures prior to STI recess.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area.

FinFETs are increasingly employed in the manufacture of integrated circuits, owing to the small size and high performance of the FinFET transistors. Fully strained channels, such as silicon germanium channels, have been used in FinFET transistors to further improve FinFET performance. However, strained channel architectures create their own shortcomings to be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor device according to embodiments of the present disclosure.

FIGS. 2A-2B, 3A-3B, 4A-4B, 5A-5B, 6A-6B, 7A-7B, 8A-8B, 9A-9C, 10A-10E, 11A-11E, and 12A-12G schematically illustrate various stages of manufacturing a semiconductor device according to embodiments of the present disclosure.

FIGS. 13A-13B, and 14 schematically illustrate stages of manufacturing a semiconductor device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Silicon germanium (SiGe) channels have been used in p-type MOS devices to enhance hole mobility. State of the art fabrication may cause different channel heights between different pattern regions. For example, semiconductor channels may have a higher channel height at areas with higher fin density and a shorter channel height at regions when lower fin density. Fin density may correspond to a ratio of surface area occupied by the fin structures over a total surface area. For instance, the semiconductor fins in ring oscillator (RO) regions, which may be part of scribe line test structures, may have a low fin density or occupy a low ratio of the total surface area than semiconductor fins in other regions, such as logic circuit regions or memory circuit regions.

For SiGe channels, the variation in channel heights may lead to SiGe height being different from the fin height. Particularly planarization process, the SiGe fins may be removed at a faster rate than dielectric materials and silicon. As a result, regions with higher SiGe density may be polished at a faster rate resulting in shorter SiGe channel height. During recess etch of shallow trench isolation, variation of SiGe channel heights may result in SiGe channels being under exposed at some regions and over exposed at other regions. When SiGe channels are under exposed, DC penalty may occur and drain-induced barrier lowering (DIBL) worsen. When SiGe channels are over exposed, AC degrades may occur.

According to the present disclosure, an implantation process is selectively performed prior to recess etching dielectric materials around semiconductor fin structures, such as semiconductor fin structures containing SiGe. The implantation process alters etching rates of the implanted dielectric materials. Subsequently, the dielectric materials are recessed to different levels at different regions resulting in different fin heights to match different channel heights.

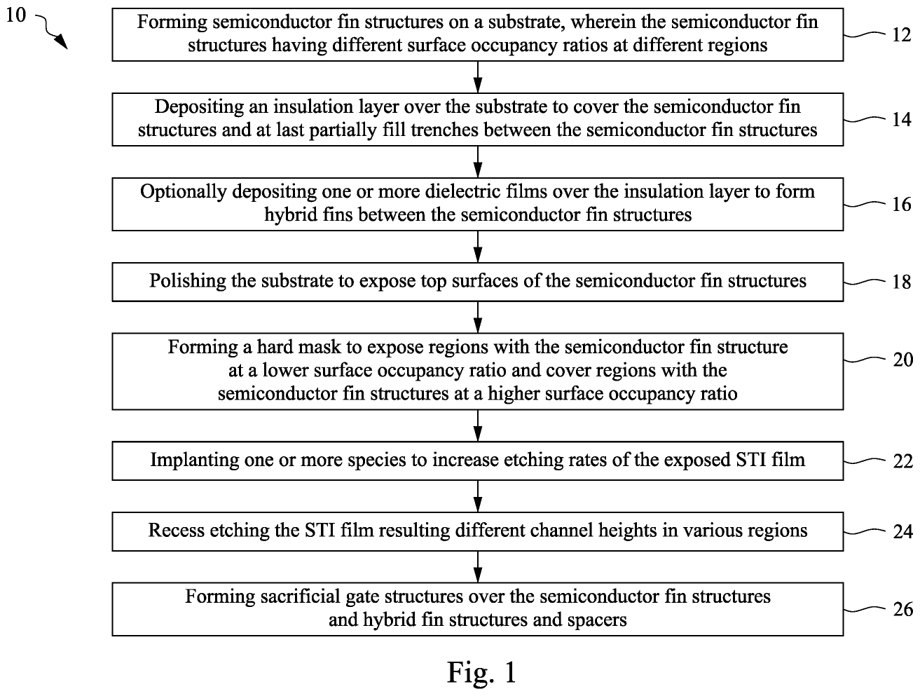

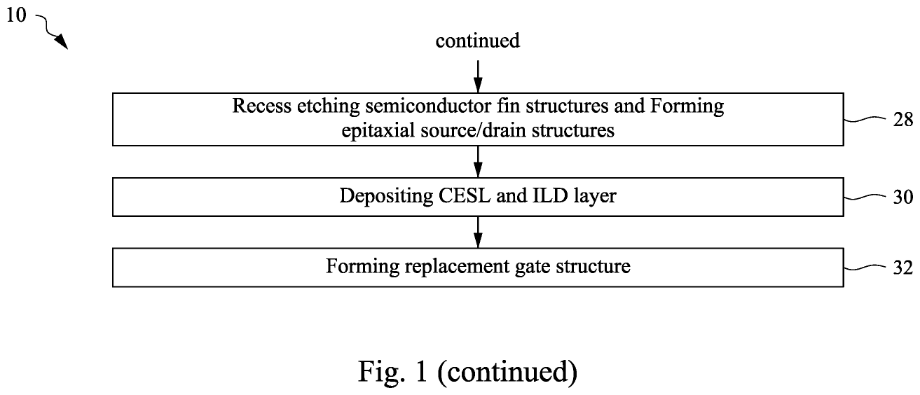

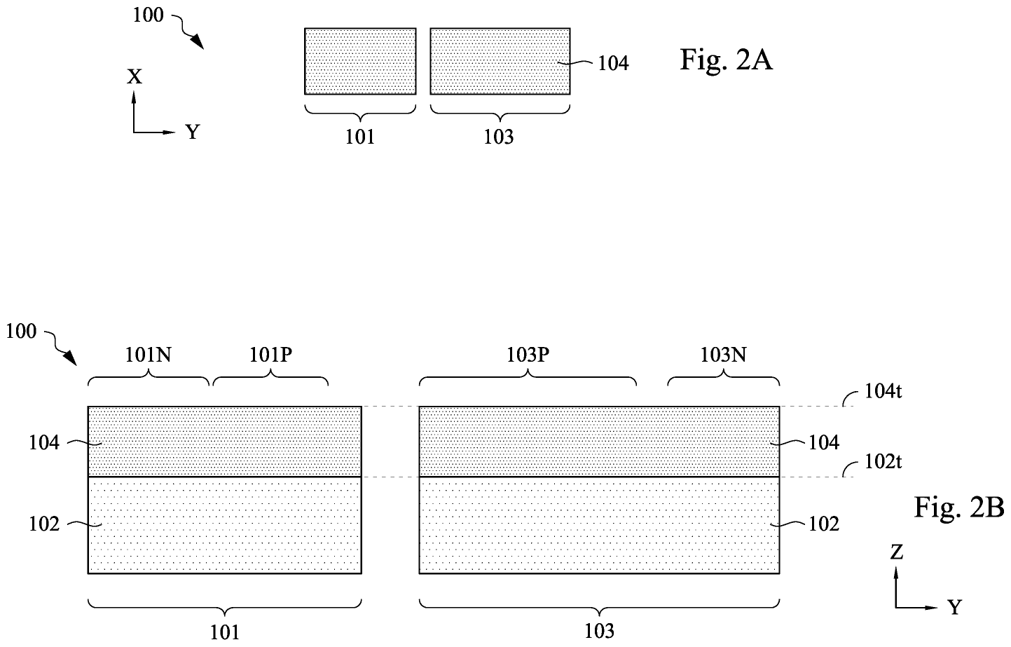

FIG. 1 is a flow chart of a method 10 for manufacturing of a semiconductor device according to embodiments of the present disclosure. FIGS. 2A-2B, 3A-3B, 4A-4B, 5A-5B, 6A-6B, 7A-7B, 8A-8B, 9A-9C, 10A-10E, 11A-11E, 12A-12G schematically illustrate various stages of manufacturing an exemplary semiconductor device 100 according to embodiments of the present disclosure. Particularly, the semiconductor device 100 may be manufactured according to the method 10 of FIG. 1.

At operation 12 of the method 10, a plurality of semiconductor fin structures are formed on a substrate 102 where the semiconductor device 100 is to be formed, as shown in FIGS. 2A-2B, 3A-3B, 4A-4B, and 5A-5B. FIGS. 2A-5A are schematic top views of the semiconductor device 100. FIGS. 2B-5B are schematic cross-sectional views of the semiconductor device 100 along B-B line in FIGS. 2A-5A. FIGS. 2A-2B, 3A-3B, 4A-4B and 5A-5B show two pattern regions 101 and 103 of the semiconductor device 100. The pattern region 101 includes semiconductor fin structures at a higher density while the pattern region 103 includes semiconductor fin structures at a lower density. For example, the pattern region 101 may be a polysilicon critical dimension (POCD) region, and the pattern region 103 may be a ring oscillator (RO) region.

The substrate 102 may be a semiconductor substrate, such as a bulk semiconductor, a semiconductor-on-insulator (SOI) substrate, or the like, which may be doped (e.g., with a p-type dopant or an n-type dopant) or undoped. The substrate 102 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, which is typically a silicon or glass substrate. Other substrates, such as a multi-layered or gradient substrate may also be used.

As shown in FIGS. 2A-2B, the pattern region 101 includes an n-type device region 101N and a p-type device region 101P. The p-type device region 101P may be for forming p-type devices, such as PMOS transistors, e.g., p-type FinFETs. The n-type device region 101N may be for forming n-type devices, such as NMOS transistors, e.g., n-type FinFETs. The p-type device region 101P may be physically separated from the n-type device region 101N by a divider, and any number of device features (e.g., other active devices, doped regions, isolation structures, etc.) may be disposed between the p-type device region 101P and the n-type device region 101N. A n-well may be formed in the p-type device region 101P in the substrate 102 by covering the n-type device region 101N with a mask (such as a photoresist, an oxide, or the like) and performing an ion implantation process. N-type dopants, such as arsenic ions, may be implanted into the p-type device region 101P. A p-well may be formed in the n-type device region 101N in the substrate 102 by covering the p-type device region 101P with a mask (such as a photoresist, an oxide, or the like) and performing an ion implantation process. P-type dopants, such as boron ions, may be implanted into the n-type device region 101N.

Similarly, the pattern region 103 includes an n-type device region 103N and a p-type device region 103P. The p-type device region 103P may be physically separated from the n-type device region 103N by a divider, and any number of device features (e.g., other active devices, doped regions, isolation structures, etc.) may be disposed between the p-type device region 103P and the n-type device region 103N. A n-well may be formed in the p-type device region 103P by selectively implanting N-type dopants, such as arsenic ions, may be implanted into the p-type device region 101P. A p-well may be formed in the n-type device region 103N of the substrate 102 selectively implanting p-type dopants, such as boron ions, may be implanted into the n-type device region 103N.

A first semiconductor layer 104 is formed over a top surface 102t of the substrate 102. The first semiconductor layer 104 is subsequently fabricated into channels for n-type devices. In some embodiments, the first semiconductor layer 104 may be used to reduce dislocation defects in a subsequently formed epitaxial layer for the p-type devices. The first semiconductor layer 104 may comprise a material such as silicon or the like. The first semiconductor layer 104 may be formed by an epitaxial growth process, such as metal-organic chemical vapor deposition (MOCVD), metal-organic vapor phase epitaxy (MOVPE), plasma-enhanced chemical vapor deposition (PECVD), remote plasma chemical vapor deposition (RP-CVD), molecular beam epitaxy (MBE), hydride vapor phase epitaxy (HVPE), liquid phase epitaxy (LPE), chloride vapor phase epitaxy (CI-VPE), or any other suitable process. The first semiconductor layer 104 may have a lattice constant similar to or the same as the lattice constants of the n-well and p-well regions in the substrate 102. In some embodiments, the first semiconductor layer 104 may have a thickness of between about 100 Å and about 5,000 Å from a top surface 104t of the first semiconductor layer 104 to the top surface 102t of the substrate 102.

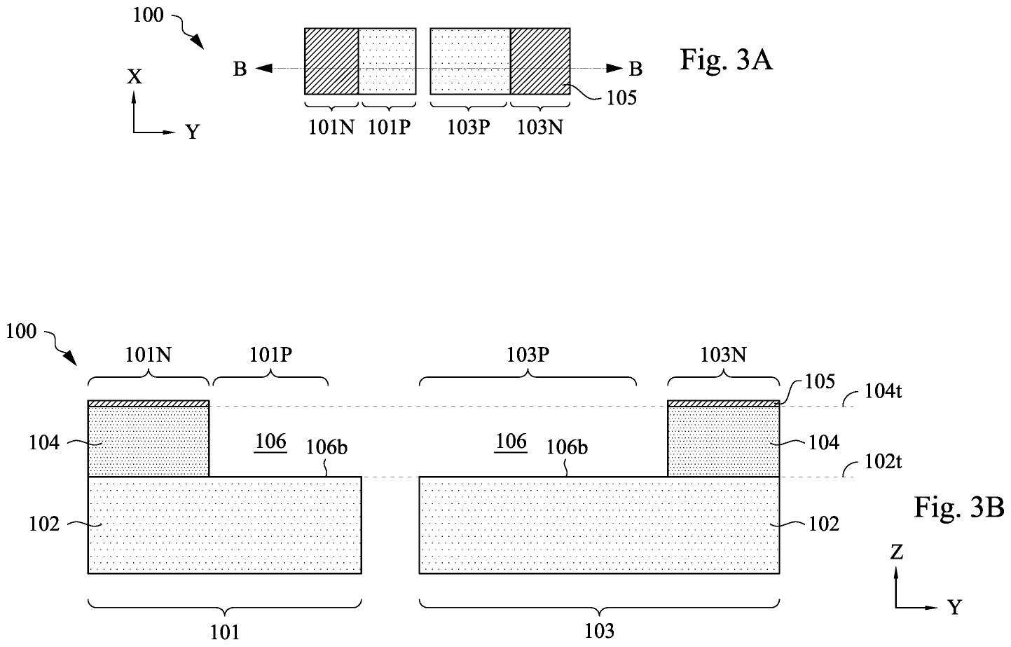

As shown in FIGS. 3A-3B, a patterned mask layer 105 is then formed over the first semiconductor layer 104 to cover the n-type device regions 101N, 103N and openings 106 over the p-type device regions 101P, 103P. A patterned photoresist, not shown, may be used as a mask to form the patterned mask layer 105 and the first semiconductor layer 104 is etched using the patterned mask layer 105 to form the openings 106. The mask layer 105 and the first semiconductor layer 104 may be etched by suitable etch processes, such as anisotropic etch processes. In some embodiments, the mask layer 105 and the first semiconductor layer 104 may be etched by dry etch processes such as reactive-ion etching (RIE), neutral-beam etching (NBE), combinations thereof, or the like. After the mask layer 105 is patterned, the patterned photoresist layer may be removed using suitable photoresist stripping techniques, such as chemical solvent cleaning, plasma ashing, dry stripping and/or the like. The patterned photoresist layer may be removed before or after etching the first semiconductor layer 104.

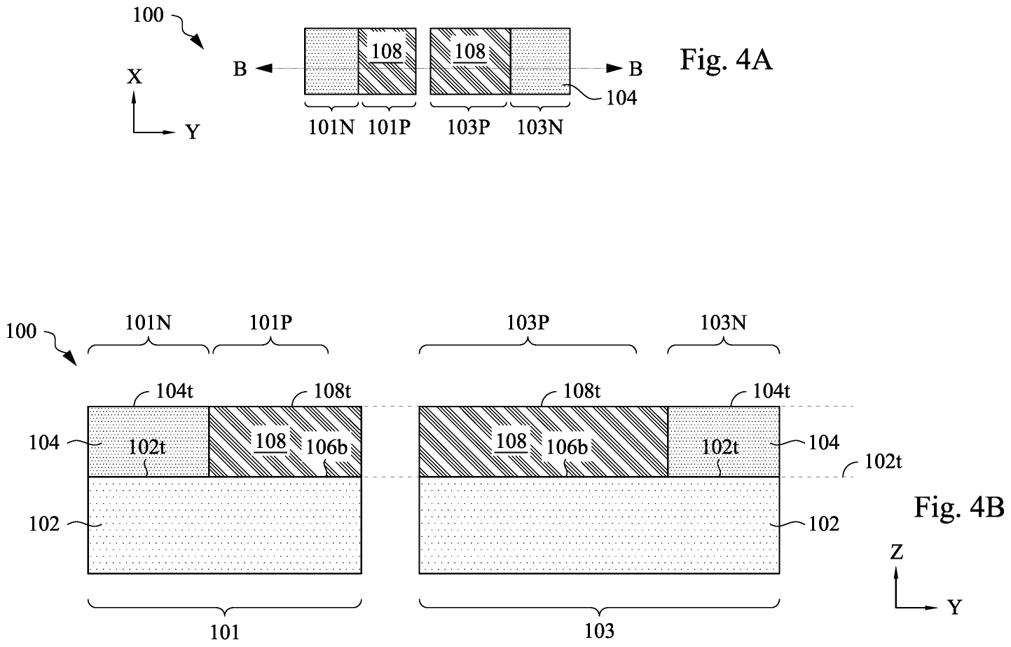

In some embodiments, the openings 106 may extend through the first semiconductor layer 104 and expose the substrate 102 and bottom surfaces 106b of the openings 106 is formed in the substrate 102. In other embodiments, at least a portion of the first semiconductor layer 104 may remain below the opening 106 and the bottom surfaces 106b of the openings 106 is. The remaining portion of the first semiconductor layer 104 may be used to grow a second semiconductor layer 108 in the openings 106 as shown in FIGS. 4A-4B. In some embodiments, the portion of the first semiconductor layer 104 remaining may have a thickness of between about 1 Å and about 300 Å after formation of the openings 112. In some embodiments, a depth of the openings 106 is between about 100 Å and about 5,000 Å.

In some embodiments, the second semiconductor layer 108 may comprise a material having a greater lattice constant than the lattice constant of the first semiconductor layer 104. For example, in some embodiments, the second semiconductor layer 108 may comprise silicon and geranium (SiGe). In some embodiments, the second semiconductor layer 108 is a strained SiGe layer comprised Ge in a range between about 25% and about 50%. SiGe channel comprises a lower bandgap than Si, allowing for greater hole mobility for subsequently formed PMOS devices. The second semiconductor layer 108 may be formed by a process such as epitaxial growth or the like. In some embodiments, the second semiconductor layer 108 is subsequently fabricated into channels for p-type devices. The second semiconductor layer 108 may be formed by an epitaxial growth process, such as metal-organic chemical vapor deposition (MOCVD), metal-organic vapor phase epitaxy (MOVPE), plasma-enhanced chemical vapor deposition (PECVD), remote plasma chemical vapor deposition (RP-CVD), molecular beam epitaxy (MBE), hydride vapor phase epitaxy (HVPE), liquid phase epitaxy (LPE), chloride vapor phase epitaxy (CI-VPE), or any other suitable process. The second semiconductor layer 108 may be made of any suitable semiconductor material, such as silicon, germanium, III-V semiconductor material, or combinations thereof.

The second semiconductor layer 108 may fill the openings 106 such that a top surface of the second semiconductor layer 108 is disposed at the same level or above a top surface of the first semiconductor layer 104. The second semiconductor layer 108 may be formed to a thickness such that a subsequent planarization process of the first semiconductor layer 104 and the second semiconductor layer 108 will create a planar surface.

After formation of the second semiconductor layer 108, the mask layer 105 is removed and a planarization process is performed on the first semiconductor layer 104 and the second semiconductor layer 108, as shown in FIGS. 4A-4B. The patterned mask layer 105 may be removed using a suitable etch process, such as a wet etch process (e.g., dilute hydrofluoric (dHF) acid, or the like). The first semiconductor layer 104 and the second semiconductor layer 108 may be planarized by any suitable planarization process, such as a chemical mechanical polish (CMP), an etch-back process, combinations thereof, or the like.

After the planarization process, a top surface 104t of the first semiconductor layer 104 may be level with a top surface 108t of the second semiconductor layer 108. In some embodiments, following the planarization process, the second semiconductor layer 108 may have a thickness of between about 100 Å and about 5,000 Å, and the first semiconductor layer 104 may have a thickness of between about 100 Å and about 5,000 Å.

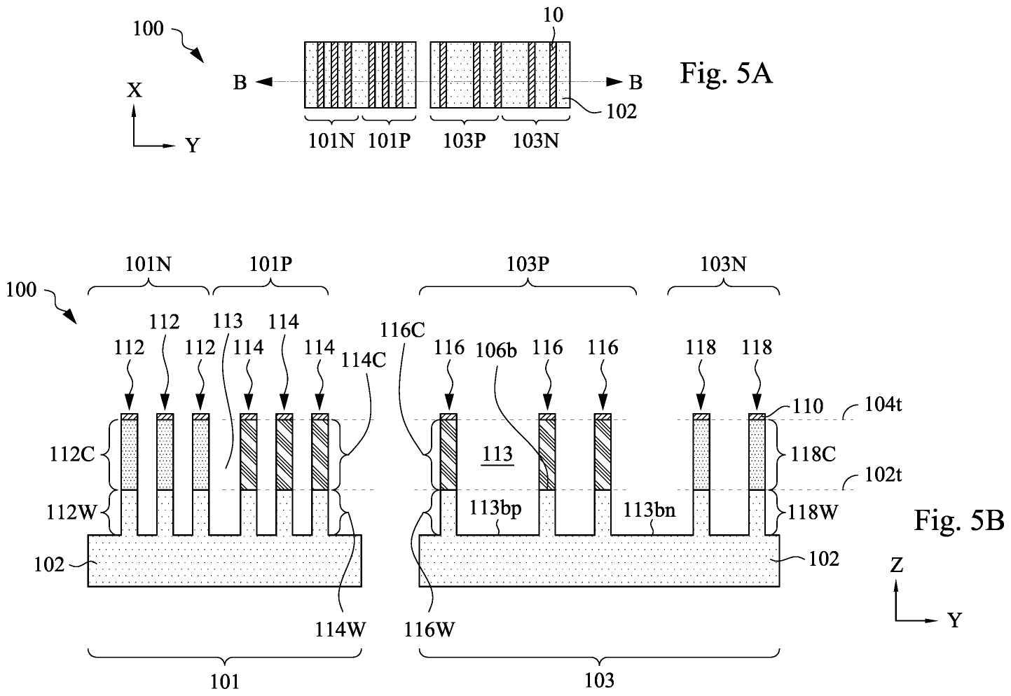

In FIGS. 5A-5B, a plurality of semiconductor fin structures 112, 114, 116, 118 are formed. The semiconductor fin structures 112, 114, 116, 118 may be formed by etching the first semiconductor layer 104, the second semiconductor layer 108, and the substrate 102 underneath using one or more mask layers patterned by any suitable method. For example, the semiconductor fin structures 112, 114, 116, 118 may be formed using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer (not shown) is formed over a substrate and patterned using a photolithography process. Spacers (not shown) are formed alongside the patterned sacrificial layer using a self-aligned process. The sacrificial layer is then removed, and the remaining spacers may then be used to pattern the substrate and form the semiconductor fin structures 112, 114, 116, 118. In FIGS. 5A-5B, a mask layer 110 is shown remaining over the semiconductor fin structures 112, 114, 116, 118. Depending on patterning process used, the hard mask layer 110 on different semiconductor fin structures may be formed from different processes with different thicknesses and/or compositions.

The first semiconductor layer 104, the second semiconductor layer 108, the n-well/p-well in the substrate 102 are etched to form the semiconductor fin structures 112, 114, 116, 118 using the mask layer 110 as a mask. Trenches 113 are formed between neighboring semiconductor fin structures 112, 114, 116, 118. The trenches 113 are formed by etching through the first semiconductor layer 104 or the second semiconductor layer 108 and into the substrate 102. The etching method may be one or more of any acceptable etch process, such as a reactive ion etch (RIE), a neutral beam etch (NBE), the like, or a combination thereof. The etching may be anisotropic. Although the semiconductor fin structures 112, 114, 116, 118 are illustrated as having vertical sidewalls and linear edges, the semiconductor fin structures 112, 114, 116, 118 may have any other suitable shape, such as having tapered sidewalls, rounded corners, or other geometrical features.

As shown in FIG. 5B, the semiconductor fin structures 112, 114 are formed in the first pattern region 101. The semiconductor fin structures 112 are formed over the n-type device region 101N. Each semiconductor fin structure 112 includes a well portion 112W formed from the p-well in the substrate 102 and a channel portion 112C formed from the first semiconductor layer 104. The semiconductor fin structures 114 are formed over the p-type device region 101P. Each semiconductor fin structure 114 includes a well portion 114W formed from the n-well in the substrate 102 and a channel portion 114C formed from the second semiconductor layer 108. The semiconductor fin structures 116, 118 are formed in the second pattern region 103. The semiconductor fin structures 116 are formed over the p-type device region 103P. Each semiconductor fin structure 116 includes a well portion 116W formed from the n-well in the substrate 102 and a channel portion 116C formed from the second semiconductor layer 108. The semiconductor fin structures 118 are formed over the n-type device region 103N. Each semiconductor fin structure 118 includes a well portion 118W formed from the p-well in the substrate 102 and a channel portion 118C formed from the first semiconductor layer 104.

At this stage, the channel portions 114C, 116C of the semiconductor fin structures 114, 116 have substantially the same height, which equals the thickness of the second semiconductor layer 108, or the distance between the bottom surface 106b and the top surface 108t. Similarly, the channel portions 112C, 118C of the semiconductor fin structures 112, 118 have substantially the same height, which equals the thickness of the first semiconductor layer 104, or the distance between the top surface 102t and the top surface 104t.

In some embodiments, the well portions 114W, 116W of the semiconductor fin structures 114, 116 have substantially the same height and the well portions 112W, 118W of the semiconductor fin structures 112, 118 have substantially the same height. In some embodiments, the trenches 113 in the n-type device regions 101N, 103N may have a different depth from the trenches 113 in the p-type device regions 101P, 103P because of different etching rates of the first semiconductor layer 104, and the second semiconductor layer 108. For example, bottom surfaces 113bp in the n-type device regions 101P, 103P are at a different Accordingly, the height of the well portions 114W, 116W may be different from the height of the well portions 112W, 118W. In some embodiments, the height of the well portions 114W, 116W may be greater than the height of the well portions 112W, 118W, or the bottom surfaces 113bp are lower than the bottom surfaces 113bn because the second semiconductor layer 108 is etched at a faster rate than the first semiconductor layer 104.

The semiconductor fin structures 116, 118 in the second pattern region 103 are at a lower density than the semiconductor fin structures 112, 114 in the first pattern region 101. As shown in FIG. 5A, a ratio of surface areas of the semiconductor fin structures 112, 114 and the overall surface area in the first pattern region 101 is higher than a ratio of surface areas of the semiconductor fin structures 116, 118 and the overall surface area in the second pattern region 103.

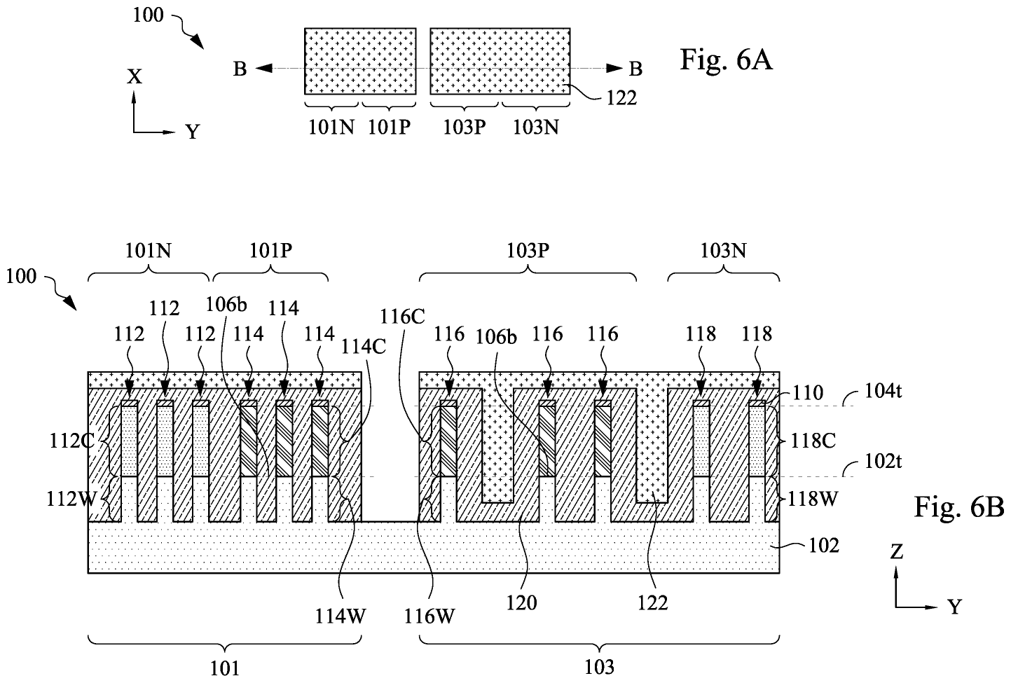

In operation 14 of the method 10, an isolation layer 120 is formed over the substrate 102, over the semiconductor fin structures 112, 114, 116, 118 and at least partially filling the trenches 112 as shown in FIGS. 6A-6B. FIG. 6A is schematic a top view of the semiconductor device 100. FIG. 6B is a schematic cross-sectional view of the semiconductor device 100 along B-B line in FIG. 6A. In some embodiments, the isolation layer 120 may include one or more layers of dielectric materials. For example, the isolation layer 120 may include a liner and a dielectric filling material over the liner.

The liner may be formed as a conformal layer, whose horizontal portions and vertical portions have thicknesses close to each other. In some embodiments, the liner may be formed by oxidizing exposed surfaces of the substrate 102, and the semiconductor fin structures 112, 114, 116, 118 in an oxygen-containing environment. In some embodiments, the liner may have a thickness of between about 1 to 5 nm. In some embodiments, the liner may comprise SiN or SiO2.

The dielectric filling material is the deposited over the liner. In some embodiments, the dielectric filling material may be deposited in a conformal manner and fill a portion of the trenches 113. As shown in FIG. 5B, the dielectric filling material of the isolation layer 120 fills the trenches 113 and leaving an opening within the wide trenches to subsequently form hybrid fin structures therein. In some embodiments, the dielectric filling material may comprise silicon oxide, silicon carbide, silicon nitride, the like, or a combination thereof, and may be formed using flowable chemical vapor deposition (FCVD), spin-on coating, CVD, ALD, high-density plasma chemical vapor deposition (HDPCVD), low pressure chemical vapor deposition (LPCVD), the like, or a combination thereof.

In operation 16 of the method 10, a dielectric fin layer 122 is formed over the isolation layer 120, as shown in FIGS. 6A-6B. The dielectric fin layer 122 is formed over the substrate 102 and covers the isolation layer 120. The dielectric fin layer 122 is filled in remaining openings in the trenches 113 in the isolation layer 120.

The dielectric fin layer 122 is formed over the substrate 102 and covers the isolation layer 120. The dielectric fin layer 122 is filled in the openings in the isolation layer 120. In some embodiments, the dielectric fin layer 122 may include silicon nitride (SiN), oxynitride, silicion carbon (SiC), silicon oxynitride (SiON), oxide, SiO2, Si3N4, SiOCN, and the like and may be formed by methods utilized to form such a layer, such as CVD, plasma enhanced CVD, sputter, and other methods known in the art. In some embodiments, the dielectric fin layer 122 may be made from low-k dielectric materials other than nitride dielectric materials. In some embodiments, the dielectric fin layer 122 may overfill the openings in the trenches 113 such that a portion of the dielectric fin layer 122 material extends above top surfaces.

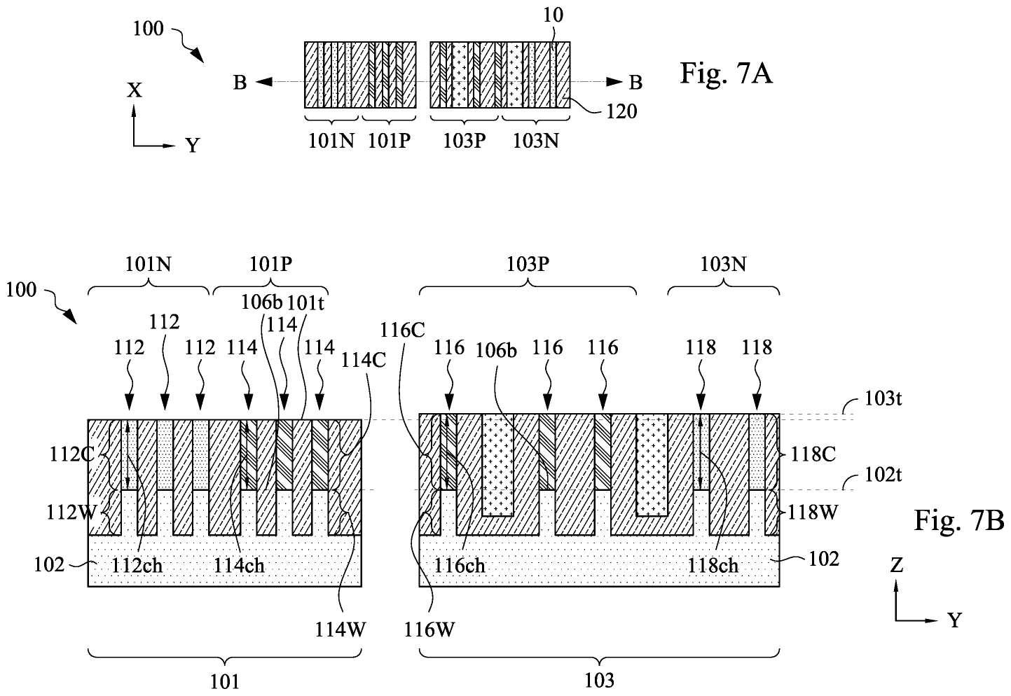

In operation 18 of the method 10, a planarization process, such as CMP, is performed to expose the semiconductor fin structures 112, 114, 116, 118 for subsequent isolation layer recess, as shown in FIGS. 7A-7B. FIG. 7A is schematic a top view of the semiconductor device 100. FIG. 7B is a schematic cross-sectional view of the semiconductor device 100 along B-B line in FIG. 7A. Different materials have different polishing rates under the same CMP condition. Variation in pattern density, i.e. density of the semiconductor fin structures 112, 114, 116, 118, or ratio of semiconductor surface occupancy, may cause CMP operations to affect different portions of the semiconductor device 100 differently. In some cases, the difference in semiconductor fin structure density may contribute to CMP loading. For example, SiGe material is polished at a faster rate than dielectric material. As result, an area with a higher ratio of SiGe surface area over dielectric surface area is polished faster than an area with a lower ratio of SiGe surface area over dielectric surface area.

As shown in FIG. 7B, the CMP loading may cause the first pattern region 101, which has a higher density of semiconductor fin structures, to have a top surface 101t lower than a top surface 103t of the second pattern region 103, which has a lower density of semiconductor fin structures. After the CMP process, channel height 112ch 114ch, 116ch, 118c of the channel portions 112C, 114C, 116C, 116C in the semiconductor fin structures 112, 114, 116, 118 are defined. The channel height 112ch of the semiconductor fin structures 112 is defined by a distance between the top surface 101t and the top surface 102t. The channel height 118ch of the semiconductor fin structures 118 is defined by a distance between the top surface 103t and the top surface 102t. The channel height 114ch of the semiconductor fin structures 114 is defined by a distance between the top surface 101t and the bottom surface 106b. The channel height 116ch of the semiconductor fin structures 116 is defined by a distance between the top surface 103t and the bottom surface 106b. Because the top surface 101t and the top surface 103t are at different levels, the channel height 114ch in the first pattern region 101 is shorter than the channel height 116ch in the second pattern region 103. Similarly, the channel height 112ch in the first pattern region 101 is shorter than the channel height 118ch in the second pattern region 103.

An etching process is subsequently performed to recess etch the isolation layer 120 to exposes a top portion of the semiconductor fin structures 112, 114, 116, 118. A height of the exposed the semiconductor fin structures 112, 114, 116, 118 over the recessed isolation layer 120 is referred to as fin height. The difference in channel heights in the first and second pattern regions 101, 103 may subsequently cause fin height not matching the corresponding channel height in some regions. Particularly for the p-type devices, the channel portions 114C, 116C and the well portions 114W, 116W include different materials, channel height and fin height mismatching may result in AD degrade or DC penalty in the resulting device. In some embodiments, the differences of channel heights are compensated by selectively implanting process, as described in operations 20 and 22.

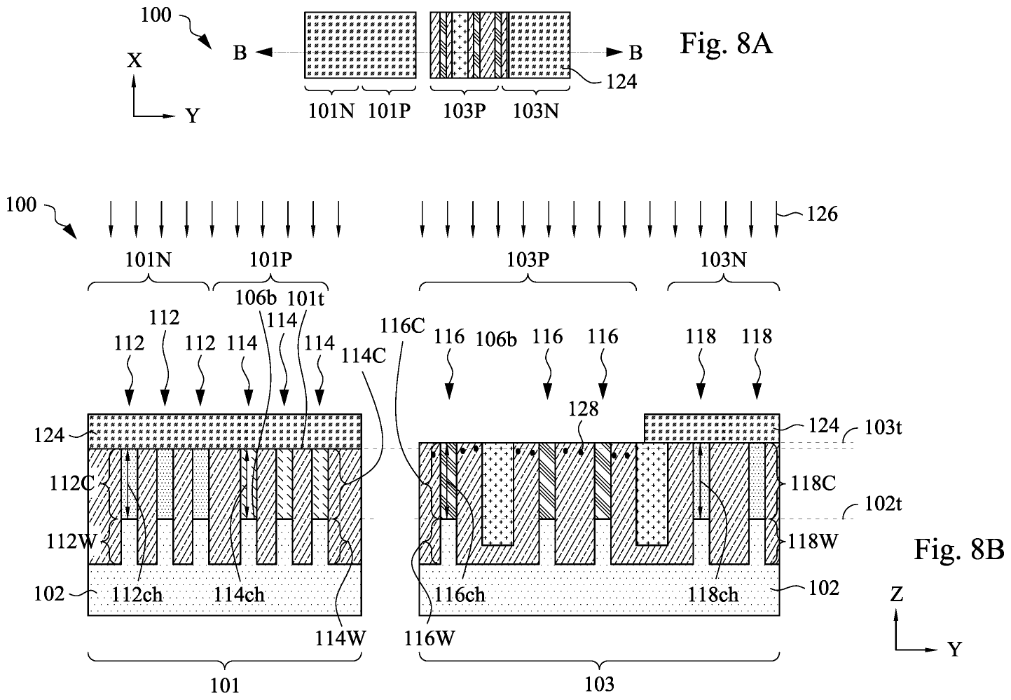

In operation 20 of the method 10, a mask layer 124 is formed over the substrate 102 and patterned to expose one or more pattern regions, as shown in FIGS. 8A-8B. FIG. 8A is schematic a top view of the semiconductor device 100. FIG. 8B is a schematic cross-sectional view of the semiconductor device 100 along B-B line in FIG. 8A. In some embodiments, the mask layer 124 is patterned to expose regions where the pattern density of the semiconductor fin structure is low. For example, the mask layer 124 is formed to expose the second pattern region 103. In some embodiments, the mask layer 124 is patterned to expose the p-type device area in one or more pattern region. For example, the mask layer 124 is patterned to expose the p-type device region 103P of the second pattern region 103.

In some embodiments, the mask layer 124 may be formed by a process such as chemical vapor deposition (CVD), atomic layer deposition (ALD), or the like. The mask layer 124 may comprise a material such as silicon dioxide, silicon nitride, or the like. The mask layer 124 may be patterned using photolithography process.

In operation 22 of the method 10, an ion implantation process is performed to implant one or more species into the exposed isolation layer 120, as shown in FIGS. 8A-8B. The isolation layer 120 in the area exposed by the hard mask layer 124, i.e. the isolation layer 120 in the p-type device region 103P of the pattern region 103 with low fin density. The exposed isolation layer 120 exposed to ion stream of a dopant as indicated by arrows 126. In some embodiments, dopant 128 enters the isolation layer 120 weakening the structure of the isolation layer 120 accelerate etching rate of the doped isolation layer 120.

Dopants and/or implantation may be selected to achieve desired etch rate alteration, such as etch rate acceleration or etch rate retardation. In some embodiments, the dopant is selected from one or more large atom species, such as geranium, argon, nitrogen, arsenic, carbon.

In the embodiment shown in FIGS. 8A-8B, the dopant is implanted to increase etch rate or etch thickness in the isolation layer 120. The ion implantation may be performed at an energy level in a range between about 3 KeV and about 10 KeV. An energy level lower than 3 KeV may not be able to drive the ion speciates deep enough to alter etch rate. An energy level higher than 10 KeV may cause damage to the semiconductor fin structures without providing additional benefit. In some embodiments, the ion implantation is performed at doping concentration in a range between 1E13 and 1E14 atoms/cm². A concentration level lower than 1E13 atoms/cm² may not be enough to alter the etch rate. A concentration level higher than 1E atoms/cm² may change to etch rate differently and/or alter the material property.

In other embodiments, the dopant may be implanted to reduce etch rate or etch thickness. For example, when the hard mask layer 124 exposes areas with a high density of semiconductor fin structures, such as the first pattern region 101, species and/or doping concentration of dopant may be selected to reduce etching thickness. In some embodiments, arsenic is doped into the isolation layer 120 at doping in a range between 5E14 and 5E15 atoms/cm² to reduce etch rate of isolation dielectric layer, such as silicon oxide.

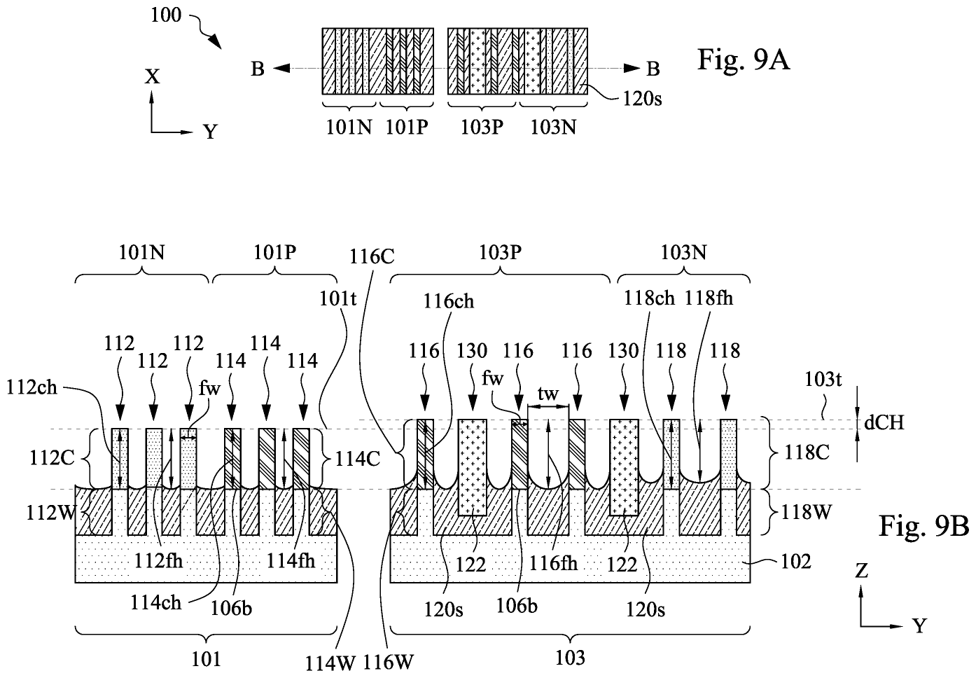

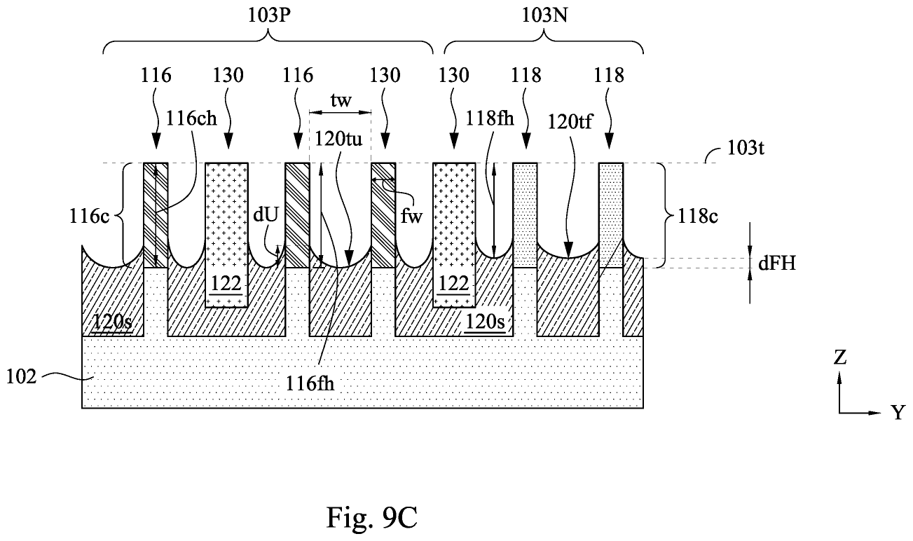

In operation 24, the isolation layer 120 is recess etched to expose the channel portions 112C, 114C, 116C, 118C of the semiconductor fin structures 112, 114, 116, 118, and form shallow trench isolation (STI) regions 120s around the well portions 112W, 114W, 116W, 118W of the semiconductor fin structures 112, 114, 116, 118, as shown in FIGS. 9A-9B. FIG. 9A is schematic a top view of the semiconductor device 100. FIG. 9B is a schematic cross-sectional view of the semiconductor device 100 along B-B line in FIG. 9A.

Prior to etching the isolation layer 120, the hard mask layer 124 is removed to expose all the isolation layer 120. The isolation layer 120 is then recessed using an acceptable etching process, such as one that is selective to the material of the isolation layer 120. In some embodiments, the isolation layer 120 may be recess etched using a dry etch process with HF/NF3, CF₄, CHF₃, NF₃, SF₆, or the like. In some embodiments, the dry etch process may be a plasma-less gaseous etching process using hydrogen fluoride (HF) gas, ammonia (NH₃) gas, or the like, a remote plasma assisted dry etch process using hydrogen (H₂), nitrogen trifluoride (NF₃), and ammonia by-products, or the like, or dilute hydrofluoric (dHF) acid.

After the isolation layer 120 is recessed, the semiconductor fin structures 112, 114, 116, 118 in the p-type device regions 101P, 103P and in the n-type device regions 101N, 101P protrude from between neighboring STI regions 120s. In some embodiments, the dielectric fin layer 122 also protrude from between neighboring STI regions 120s forming hybrid fin structures 130. The hybrid fin structures 130 may be disposed in the first region 101 and/or the second region 103. For example, the hybrid fin structures 130 may be disposed between the semiconductor fin structures 116, 118 to divide p-type devices from n-type devices. The hybrid fin structures 130 may be disposed between the neighboring semiconductor fin structures 116 or 118.

The semiconductor fin structures 112, 114, 116, 118 protrude from the STI region 120s at fin heights 112fh, 114fh, 116fh, 118fh respectively. The fin heights 112fh, 114fh, 116fh, 118fh are defined as distances between top surfaces 112t, 114t, 116t, 118t of the semiconductor fin structures 112, 114, 116, 118 and a top surface 120t of the STI region 120s. The top surfaces 112t and 114t are substantially at the same level and substantially the same as the top surface 101t of the first pattern region 101. The top surfaces 116t and 118t are substantially at the same level and substantially the same as the top surface 103t of the second pattern region 103.

Because of the selective implantation process at operation 22 changes etching rate of the isolation layer 120, the isolation layer 120 at implanted areas may be etched faster or slower than the isolation layer 120 at non-implanted areas. In the embodiment of FIGS. 9A-9B, the isolation layer 120 in the p-type device region 103P in the second pattern region 103, which has lower density of semiconductor fin structures. The selective implantation to the isolation layer 120 in the p-type device region 103P increases the etch rate resulting in a larger etching depth than the non-implanted regions, such as the p-type device region 101P and n-type device region 101N of the first pattern region 101, and the n-type device region 103N of the second pattern region 103. As shown in FIG. 9B, the top surface 120t of the STI region 120s is at different levels at different regions, which enable different fin heights to avoid mismatch between fin heights and channel heights in the p-type device regions.

The isolation layer 120 around the semiconductor fin structures 112, 114, 118 is not implanted, therefore, is etched to the substantially the same level and the fin heights 112fh, 114fh, and 118fh are substantially the same. The isolation layer 120 around the semiconductor fin structure 116 is implanted to accelerate etch rate, therefore is etched to a deeper level and the fin heights 116fh is greater than the fin heights 112fh, 114fh, and 118fh. Both the channel portions 112C, 118C and the well portions 112W, 118W of the semiconductor fin structures 112, 118 for the n-type device include silicon, difference between fin heights and channel height does not cause the same problems as with the semiconductor fin structures 114, 116 for the p-type device. In some embodiments, operation parameters of the implantation process in operation 22 may be selected to compensate difference between the channel heights 114ch, 116ch, and operation parameters of the recess etching in operation 24 may be selected to match the fin height 114fh to the channel height 114ch. As shown in FIG. 9B, the fin height 114fh is substantially the same as the channel height 114ch, the fin height 116fh is substantially the same as the channel height 116ch, while the fin height 116fh in areas with lower fin density is higher than the fin height 114fh in the areas with higher fin density. The fin height difference dFh (shown FIG. 9C) is similar to the channel height difference dCh.

After the STI recess operation, the channel heights 112ch, 114ch, 116ch, 118ch may be in a range between about 40 to 60 nm. The channel height difference dCh between the channel heights 112ch, 114ch, 116ch, 118ch may be up to about 6 nm, or about up to 10% of the channel heights. The fin heights 112fh, 114fh, 116fh, 118fh may be in a range between about 40 to 60 nm. The protruding portions of the semiconductor fin structures 112, 114, 116, 118 may have a fin width fw in a range between about 5 nm and about 10 nm. In some embodiments, trench widths tw between protruding portions of the semiconductor fin structures 112, 114, 116, 118 and hybrid fin structure 130 may be in a range between about 5 nm and about 30 nm. The selected implantation may enable a fin height difference dFh in a range between about 2 nm and about 4 nm, or in a range between about 3% and 10% of the fin heights. A fin height difference dFh less than 2 nm or 3% of the fin heights 112fh, 114fh, 116fh, 118fh may not provide enough benefit to adjust the cost of added patterning and implantation process. A fin height difference dFh more than 4 nm or 10% of the fin heights 112fh, 114fh, 116fh, 118fh may induce opposite channel height/fin height mismatching.

FIG. 9C is a partial enlarged view of the semiconductor device 100 of FIG. 9B. As shown in FIG. 9C, the fin height 116fh for the p-type device is greater than the fin height 118fh for the corresponding n-type device in the pattern region 103. In some embodiments, the top surface 120t of the STI region 120s in the implanted region has a non-linear profile 120tu, such as a hyperbolic surface, curvature surface, half-bulb/sphere-like surface, facet surface, necking surface, notching surface, or other surfaces not planar with a horizontal surface in the x-y plane. In some embodiments, the non-linear profile 120tu may be a U-shaped profile in which the top surface 120t of the STI region 120s is higher near the semiconductor fin structures 116 and lower near the center, as shown in FIGS. 9B and 9C. In some embodiments, a height difference dU in the U-shaped non-linear profile 120tu is in a range between 2 nm and 4 nm. In contrast, the top surface 120t of the STI region 120s without implantation, such as the STI region 120s around the semiconductor fin structures 112, 114, 118, has a relative planar profile 120tf, compared to the non-linear profile 120tu.

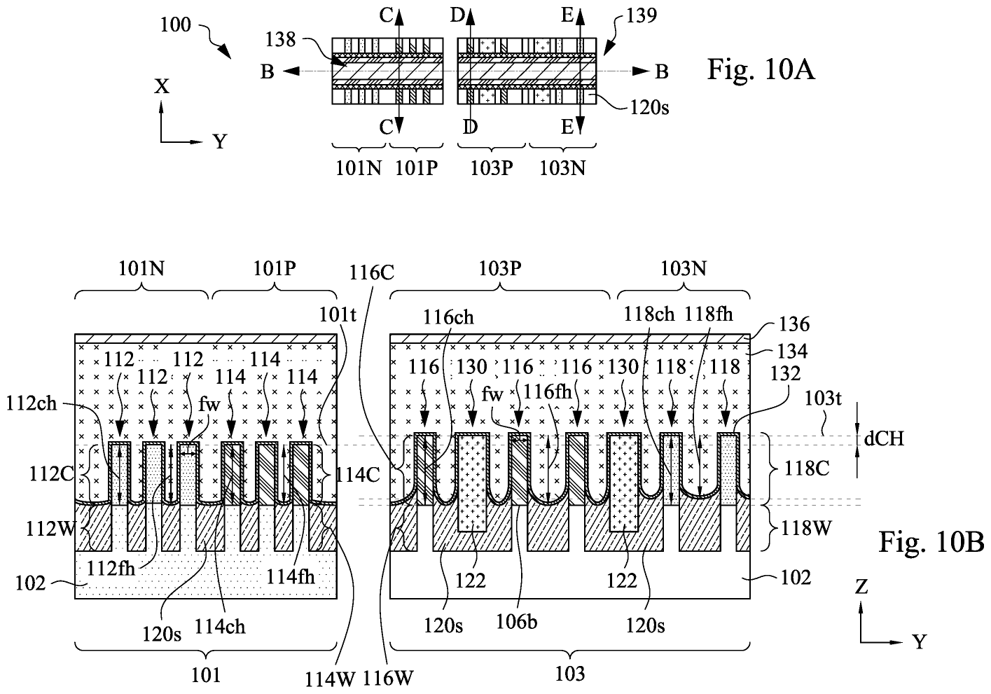

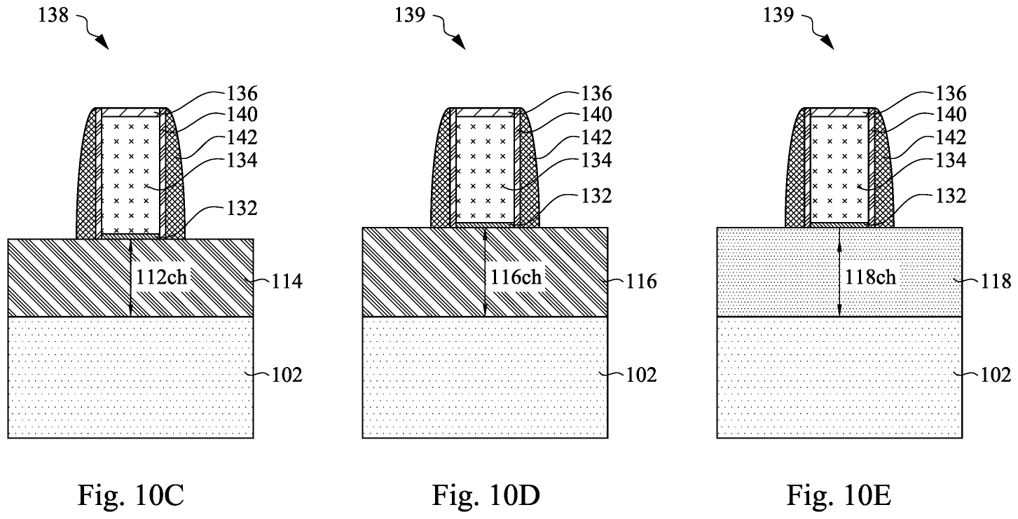

In operation 26 of the method 10, sacrificial gate structures 138, 139 are formed over the semiconductor fin structures 112, 114, 116, 118, the hybrid fin structure 130, and the STI region 120s, and sidewall spacers 140, 142 formed on sidewalls of the sacrificial gate structures 138, 139, as shown in FIGS. 10A-10E. FIG. 10A is a plan view of the semiconductor device 100. FIGS. 10B-10E are cross-sectional views of the semiconductor device 100 along lines B-B, C-C, D-D, and E-E respectively.

In some embodiments, a cap layer, not shown, may be formed on exposed portions of the semiconductor fin structures 112, 114, 116, 118 prior to formation of the sacrificial gate structures 138, 139. The cap layer may reduce out-diffusion of germanium from the semiconductor fin structures 116 into subsequently formed overlying layers. The cap layer may be formed of silicon, for example poly-crystalline silicon, or the like. The cap layer may have a thickness of between about 1 Å and about 10 Å.

The sacrificial gate structures 138, 139 are formed over portions of the semiconductor fin structures 112, 114 in the first pattern region 101, and the semiconductor fin structures 116, 118 in the second pattern region 103 respectively. The sacrificial gate structures 138, 139 may include a sacrificial gate dielectric layer 132, a sacrificial gate electrode layer 134, and a mask layer 136.

The sacrificial gate dielectric layer 132 may be formed conformally over the semiconductor fin structures 112, 114, 116, 118, the hybrid fin structures 130, and the STI region 120s. In some embodiments, the sacrificial gate dielectric layer 132 may be deposited by a CVD process, a sub-atmospheric CVD (SACVD) process, a FCVD process, an ALD process, a PVD process, or other suitable process. The sacrificial gate dielectric layer 132 may include one or more layers of dielectric material, such as SiO₂, SiN, a high-k dielectric material, and/or other suitable dielectric material.

The sacrificial gate electrode layer 134 may be blanket deposited on the over the sacrificial gate dielectric layer 132. The sacrificial gate electrode layer 134 includes silicon such as polycrystalline silicon or amorphous silicon. The thickness of the sacrificial gate electrode layer is in a range between about 40 nm and about 200 nm. In some embodiments, the sacrificial gate electrode layer 134 is subjected to a planarization operation. The sacrificial gate electrode layer 134 may be deposited using CVD, including LPCVD and PECVD, PVD, ALD, or other suitable process.

Subsequently, the mask layer 136 are formed over the sacrificial gate electrode layer 134. A pad layer, not shown, may be deposited on the sacrificial gate electrode layer 134 prior to forming the mask layer 136. The pad layer may include silicon nitride. The mask layer 136 may include silicon oxide. Next, a patterning operation is performed on the mask layer 136, the sacrificial gate electrode layer 134 and the sacrificial gate dielectric layer 132 to form the sacrificial gate structures 138, 139.

The sidewall spacers 140, 142 are formed on sidewalls of each sacrificial gate structures 138, 139, as shown in FIGS. 10A, 10C, 10D, and 10E. After the sacrificial gate structures 138, 139 are formed, the sidewall spacers 140, 142 are formed on sidewalls of the sacrificial gate structures 138, 139,

In some embodiments, the sidewall spacers 140, 142 may be formed on sequentially on exposed sidewalls of the sacrificial gate structures 138, 139, and the semiconductor fin structures 112, 114, 116, 118. Each of the sidewall spacers 140, 142 may be formed by a blanket deposition followed by an anisotropic etch to remove the sidewall spacers 140 from horizontal surfaces. Although two layers of sidewall spacers are shown, the sidewall spacers may include more or less layers of dielectric material. In some embodiments, the sidewall spacers 140, 142 may be formed by ALD or CVD. In some embodiments, the insulating material of the sidewall spacers 140, 142 may include dielectric material selected from silicon oxide, silicon nitride, such as Si₃N₄, carbon doped silicon oxide, nitrogen doped silicon oxide, porous silicon oxide, or combination thereof.

FIGS. 10C, 10D, 10E schematically illustrate that the sacrificial gate structures 138, 139 and the sidewall spacers 140, 142 over the semiconductor fin structures 114, 116, 118 respectively. As shown in FIGS. 10C, 10D, the channel length 114ch in the first pattern region 101 is shorter than the channel length 116ch in the second pattern region 103.

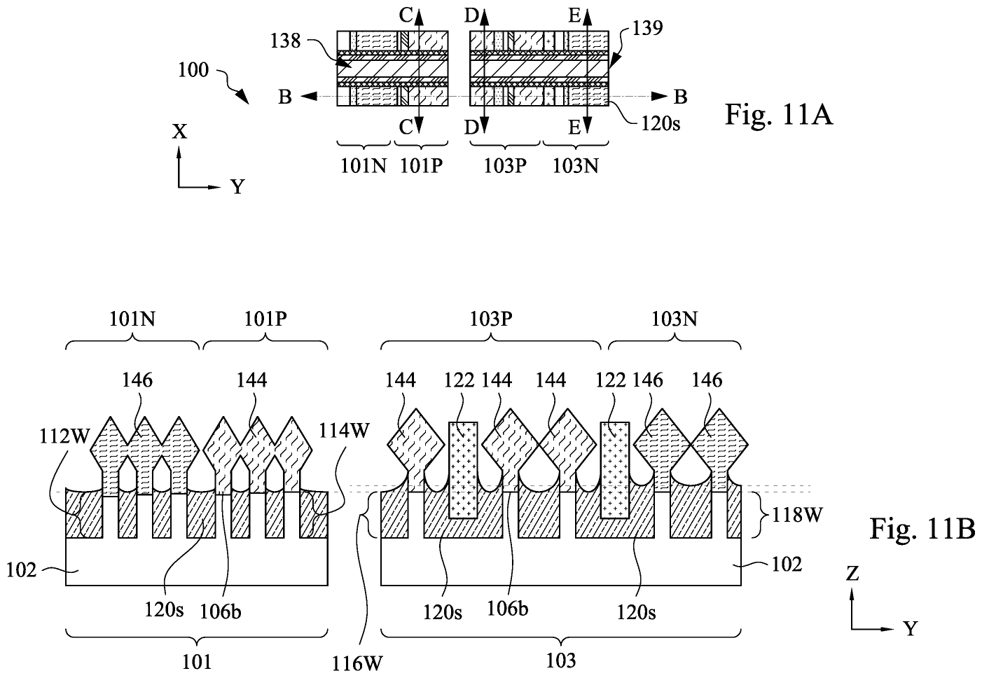

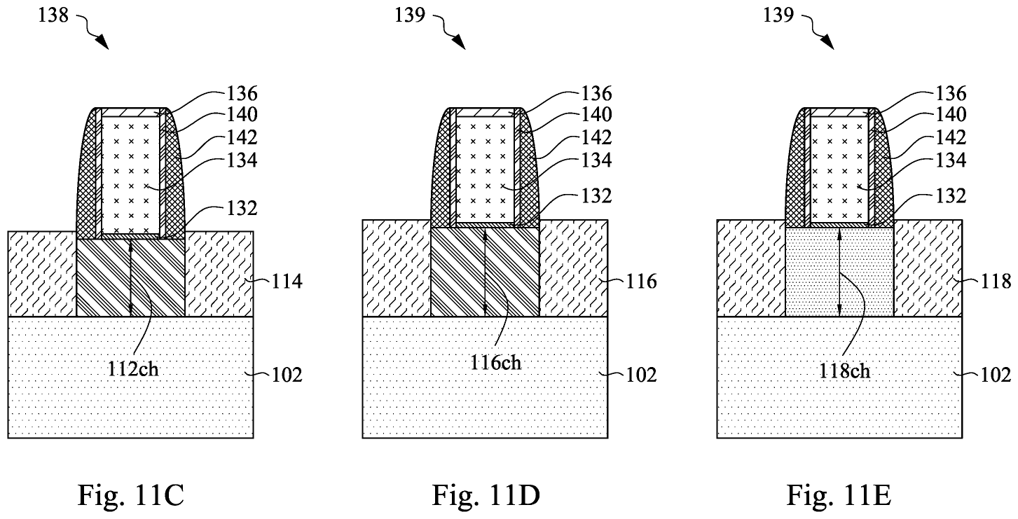

At operation 28 of the method, the semiconductor fin structures 112, 114, 116, 118 not covered by the sacrificial gate structures 138, 139 are etched back and epitaxial source/drain features 144, 146, as shown in FIGS. 11A-11E. FIG. 11A is a plan view of the semiconductor device 100. FIGS. 11B-11E are cross-sectional views of the semiconductor device 100 along lines B-B, C-C, D-D, and E-E respectively. Even though described together, regions for p-type devices, such as the p-type device regions 101P, 103P, and regions for n-type devices, such as the n-type device regions 101N, 103N, may be performed separately using patterned masks and different processing recipes.

The semiconductor fin structures 112, 114, 116, 118 not covered by the sacrificial gate structures 138, 139 and the sidewall spacers 140, 142 are etched to expose well portions 112W, 114W, 116W, 118W of each semiconductor fin structure 112, 114, 116, 118. In some embodiments, suitable dry etching and/or wet etching may be used to remove the channel portions 112C, 114C, 116C, 118C. The epitaxial source/drain features 146 for N-type devices and the epitaxial source/drain features 144 for the P-type devices are epitaxially grown from exposed semiconductor surfaces of the semiconductor fin structures 112, 114, 116, 118.

The epitaxial source/drain features 144 for the p-type device may include one or more layers of Si, SiGe, Ge with p-type dopants, such as boron (B). In some embodiments, the epitaxial source/drain features 144 may be SiGe material including boron as dopant. The epitaxial source/drain features 144 shown in FIG. 11B has a substantially diamond shape in cross section. However, the epitaxial source/drain features 144 may be other shapes according to the design. The epitaxial source/drain features 146, 232p may be formed by any suitable method, such as by CVD, CVD epitaxy, molecular beam epitaxy (MBE), or any suitable deposition technique.

The epitaxial source/drain features 146 for n-type devices may include one or more layers of Si, SiP, SiC and SiCP. The epitaxial source/drain features 146 also include N-type dopants, such as phosphorus (P), arsenic (As), etc. In some embodiments, the epitaxial source/drain features 146 may be a Si layer includes phosphorus (P) dopants. The epitaxial source/drain features 146 shown in FIG. 11B has a substantially diamond shape in cross section. However, the epitaxial source/drain features 146 may be other shapes according to the design.

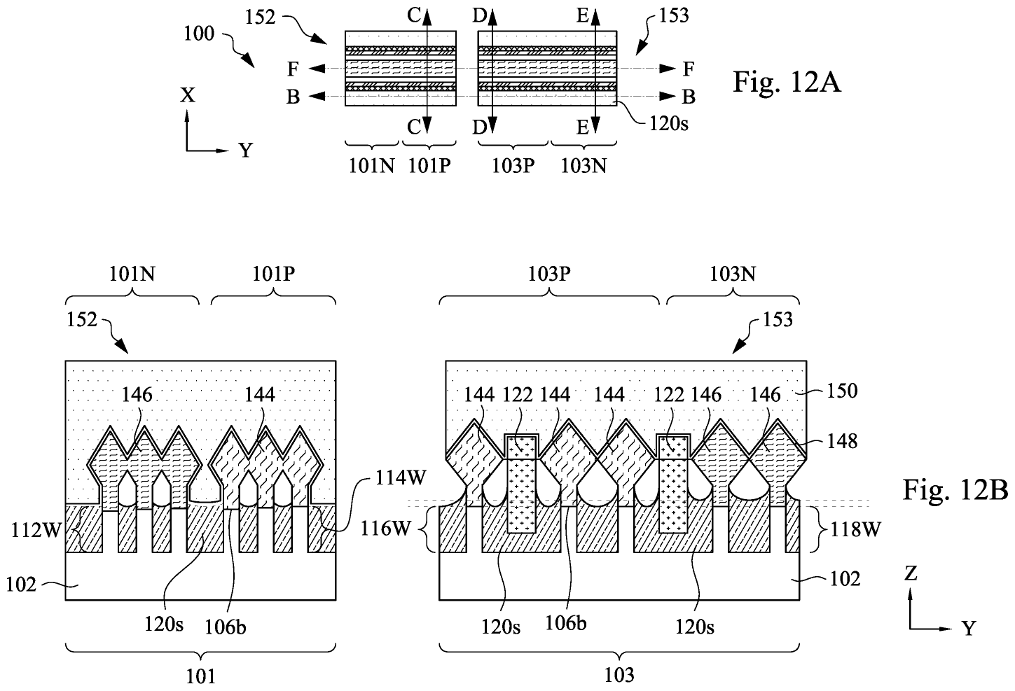

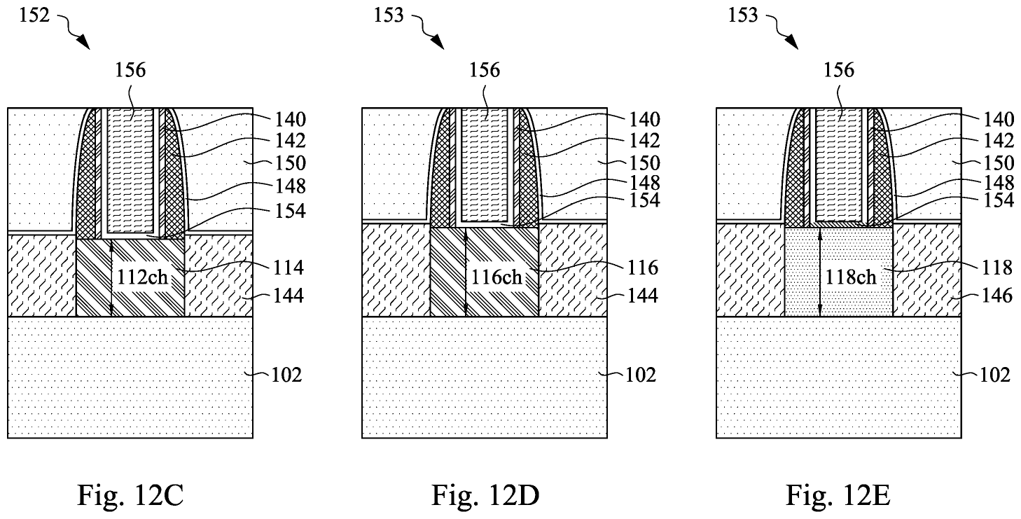

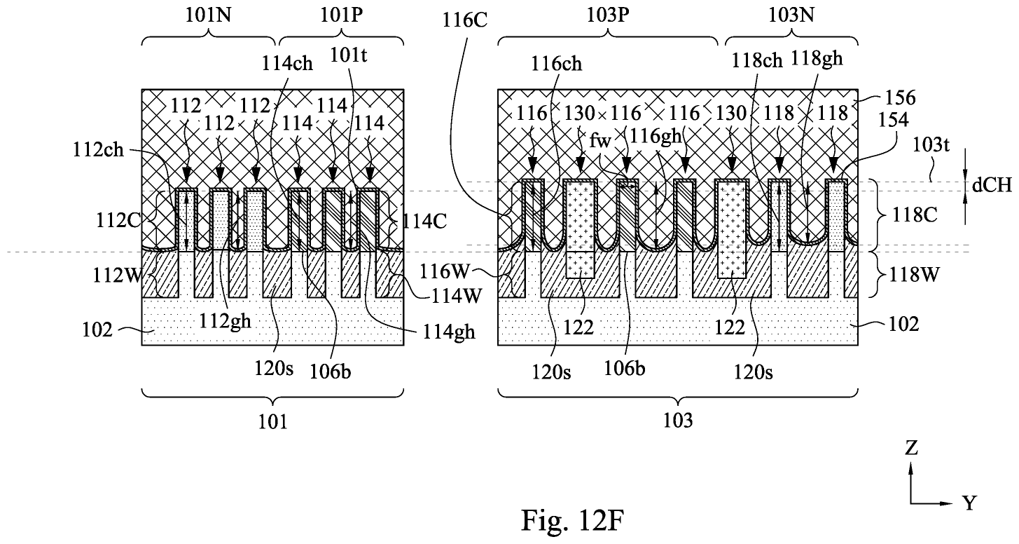

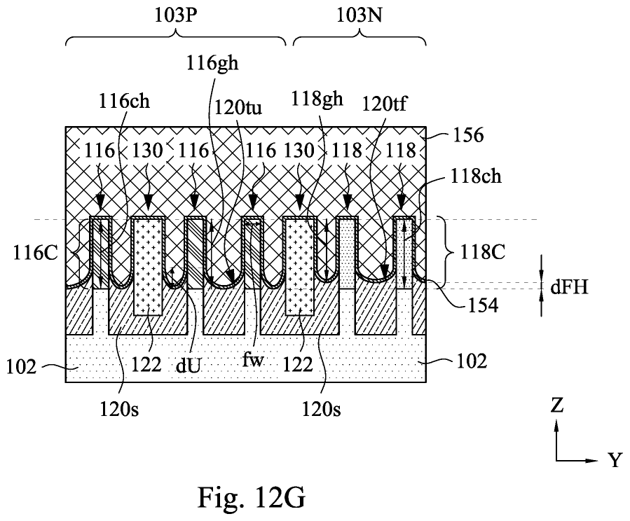

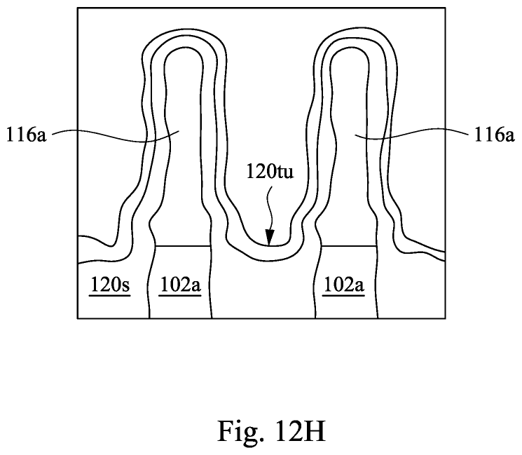

At operation 30 of the method 10, a contact etch stop layer (CESL) 148 and an interlayer dielectric (ILD) layer 238 are conformally formed over the semiconductor substrate, as shown in FIGS. 12A-12G. FIG. 12A is a plan view of the semiconductor device 100. FIGS. 12B-12F are cross-sectional views of the semiconductor device 100 along lines B-B, C-C, D-D, E-E, F-F respectively. FIG. 12G is a partial enlarged view of FIG. 12F.

The CESL 148 may by uniformally formed over exposed surfaces of the semiconductor device 100. The CESL 148 formed on exposed surfaces of the epitaxial source/drain features 146, 144, exposed surfaces of the sidewall spacers 140, 142, and exposed surfaces of the STI region 120s. The CESL 148 acts as an etch stop to provide protection to the source/drain features 146, 144 during formation of source/drain contact features. The CESL 148 may include Si₃N₄, SiON, SiCN or any other suitable material, and may be formed by CVD, PVD, or ALD.

The ILD layer 150 is formed over the CESL 148. The materials for the ILD layer 150 include compounds comprising Si, O, C, and/or H, such as silicon oxide, SiCOH and SiOC. Organic materials, such as polymers, may be used for the ILD layer 150. In some embodiments, the ILD layer 150 may be formed by flowable CVD (FCV). The ILD layer 150 protects the epitaxial source/drain features 146, 232p during the removal of the sacrificial gate structures 138, 139. A planarization process, such a CMP process, may be performed after the deposition of the material for the ILD layer 150 to expose to the sacrificial gate structures 138, 139 for the subsequent processing.

FIG. 12B schematically illustrates that the CESL 148 and ILD layer 150 formed over the epitaxial source/drain features 144, 146, and exposed areas of the STI region 120s. FIGS. 12C, 12D, 12E schematically illustrate that the CESL 148 is formed on the sidewall spacers 142 and on the epitaxial source/drain features 144, 146.

At operation 32 of the method 10, the sacrificial gate structures 138, 139 are removed and replacement gate structures 152, 153 are formed respectively, as shown in FIGS. 12A-12G. The sacrificial gate dielectric layer 132 and the sacrificial gate electrode layer 134 are removed using dry etching, wet etching, or a combination. The channel portions 112C, 114C, 116C, 118C of the semiconductor fin structures 112, 114, 116, 118 are exposed and forming gate cavities between the sidewall spacers 140. Replacement gate structures 152, 153 are then filled in the gate cavities. The replacement gate structures 152, 153 including a gate dielectric layer 154 and a gate electrode layer 156.

The gate dielectric layer 154 may include different compositions for n-type devices and p-type devices and are formed separately using patterned mask layers and different deposition recipes. In some embodiments, an interfacial layer (not shown) may be formed on the channel portions 112C, 114C, 116C, 118C prior to formation of the gate dielectric layer 154. The gate dielectric layer 154 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 154 may be formed by CVD, ALD or any suitable method.

The gate electrode layer 156 is formed on the gate dielectric layer 154 to fill the gate cavities. The gate electrode layer 156 may include one or more layers of conductive material, such as tungsten, aluminum, copper, titanium, tantalum, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 156 may be formed by CVD, ALD, electro-plating, or other suitable method. In some embodiments, the gate electrode layer 156 may include different conductive materials and formed in different processes. Alternatively, the gate electrode layer 156 may include the same conductive material, and formed in the same process. After the formation of the gate electrode layer 156, a planarization process, such as a CMP process, is performed to remove excess deposition of the gate electrode material and expose the top surface of the ILD layer 150.

FIG. 12F schematically illustrates that the gate dielectric layer 154 formed on surfaces of the semiconductor fin structures 112, 114, 116, 118 protruding over the STI region 120s and not covered by the sidewall spacers 140, 142. Interfaces between the gate dielectric layer 154 and the semiconductor fin structures 112, 114, 116, 118 allow the potential applied to the gate electrode layer 156 to control current flows through the channel portions 112C, 114C, 116C, 118C respectively. Heights of the interfaces along the z-direction between the gate dielectric layer 154 and the semiconductor fin structures 112, 114, 116, 118 may be referred to as gate heights 112gh, 114gh, 116gh, 118gh respectively. Because fin heights 114fh, 116fh of the SiGe-containing semiconductor fin structures 114, 116 substantially match the channel heights 114ch and 116ch which are different due to pattern density, the gate heights 114gh, 116gh also match the channel heights 114ch, 116ch.

FIG. 12F is a partial enlarged view of the semiconductor device 100 of FIG. 12E. As shown in FIG. 12F, the gate height 116gh for the p-type device is greater than the gate height 118gh for the corresponding n-type device in the pattern region 103. The gate height 118gh for the n-type device is shorter than the channel height 118ch. The gate dielectric layer 154 and the gate electrode layer 156 have a profile matching profiles of the top surface 120t of the STI region 120s. The gate dielectric layer 154 and the gate electrode layer 156 between neighboring semiconductor fin structures 116 for the p-type device have a non-linear profile, such as a hyperbolic surface, curvature surface, half-bulb/sphere-like surface, facet surface, necking surface, notching surface, or other surfaces not planar with a horizontal surface in the x-y plane. Particularly, the gate dielectric layer 154 and the gate electrode layer 156 between neighboring semiconductor fin structures 116 for the p-type device have such as the U-shape profile shown in FIG. 12F. The gate dielectric layer 154 and the gate electrode layer 156 between neighboring semiconductor fin structures 118 for the n-type device have a relative planar profile.

As shown in FIG. 12G is a graph showing a pair of SiGe-containing semiconductor fin structure 116a which are formed over silicon substrate 102a. Isolation layer 120a is formed around and over the semiconductor fin structure 116a, and the substrate 102a. A CMP process is performed to expose top surfaces of the semiconductor fins 116a. An implantation, similar to the implantation in operation 22 discussed above, is then performed to the isolation layer 120a. An etch is then performed to recess the isolation layer 120a and expose the semiconductor fins 116a. As shown in FIG. 12G, the isolation layer 120a between the semiconductor fins 116a has a U-shaped profile.

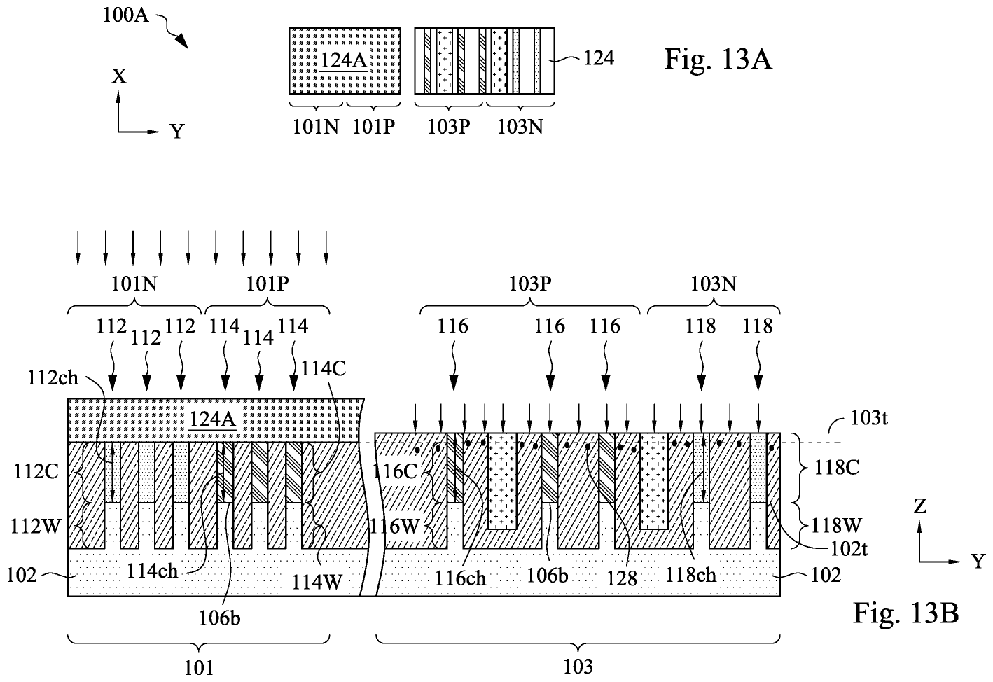

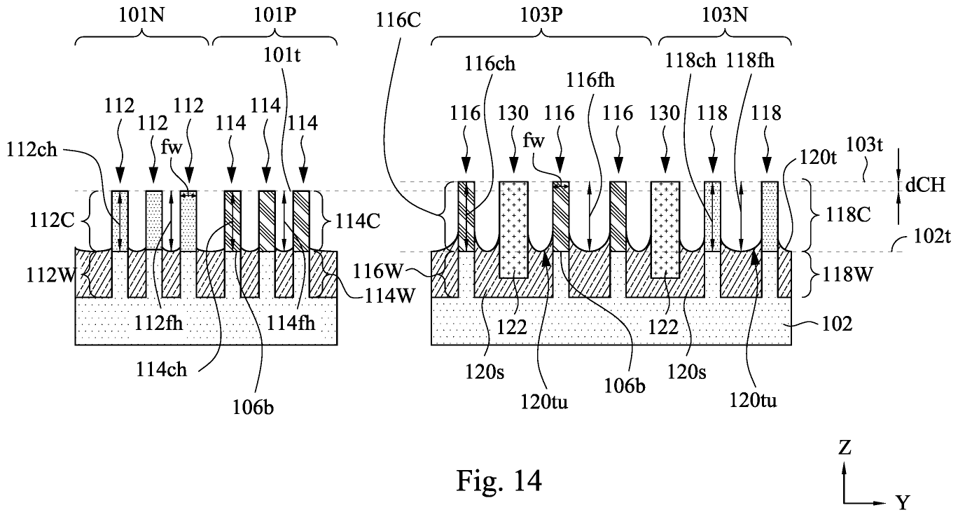

FIGS. 13A-13B and FIG. 14 schematically illustrate a semiconductor device 100A according to another embodiment of the present disclosure. The semiconductor device 100A is fabricated according to the method 10 except during operation 20, a hard mask layer 124A is formed to expose both the p-type device region 103P and the n-type device region 103N during implantation. After recess of the isolation layer 120 in operation 24, fin heights 118fn′ is substantially the same as the channel height 118Ch, and the top surface 120t of the STI region 120s in the n-type device region 103n is non-linear as in the n-type device region 103p.

Various embodiments or examples described herein offer multiple advantages over the state-of-art technology. By implanting the isolation layer with implants to alter etching rate of the isolation layer prior to STI recess, embodiments of the present disclosure provide a solution to address any issues caused by non-uniform channel heights across a substrate. Particularly, embodiments of the present disclosure improve DIBL, and reduces DC/AC penalty in p-type devices with SiGe channels.

Some embodiments of the present provide a semiconductor device comprising a STI (shallow trench isolation) region; a first semiconductor fin structure extending from a top surface of the STI region for a first fin height, wherein the first semiconductor fin structure is disposed in a first region; and a second semiconductor fin structure extending from the top surface of the STI region for a second fin height, wherein the second semiconductor fin structure is disposed in a second region, the second fin height is greater than the first fin height, and each of the first and second semiconductor fin structures comprises: a channel portion of a first composition; and a well portion of a second composition, wherein the channel portion disposed on the well portion.

Some embodiments of the present disclosure provide a semiconductor device comprising a first pattern region comprising: a first STI region; first semiconductor fin structures for n-type devices extending from a top surface of the first STI region, wherein the top surface of the first STI region has a planar profile between neighboring first semiconductor fin structures; and second semiconductor fin structures for p-type devices extending from the top surface of the first STI region, wherein the top surface of the first STI region has a U-shaped profile between neighboring second semiconductor fin structures.

Some embodiments of the present disclosure provide a method comprising forming first semiconductor fin structures on a first region of a substrate, second semiconductor fin structures on a second region of the substrate, wherein the region has a first pattern density, the second region has a second pattern density, and the first pattern density is greater than the second pattern density; depositing an isolation layer over the first and second semiconductor fin structures; planarizing the substrate to expose the first and second semiconductor fin structures; forming a hard mask over the substrate to expose the second semiconductor fin structures and the isolation layer around the second semiconductor fin structures; implanting one or more species into exposed portion of the isolation layer; remove the hard mask; and etching back the isolation layer to partially expose the first and second semiconductor fin structures, wherein the first semiconductor fin structures have a first fin height extending from a top surface of the isolation layer, the second semiconductor fin structures have a second fin height extending from the top surface of the isolation layer, and the second fin height is greater than the first fin height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a STI (shallow trench isolation) region;
a first semiconductor fin structure extending from a top surface of the STI region for a first fin height, wherein the first semiconductor fin structure is disposed in a first region; and
a second semiconductor fin structure extending from the top surface of the STI region for a second fin height, wherein the second semiconductor fin structure is disposed in a second region, the second fin height is greater than the first fin height, and each of the first and second semiconductor fin structures comprises:
a channel portion of a first composition; and
a well portion of a second composition, wherein the channel portion disposed on the well portion.

2. The semiconductor device of claim 1, wherein the first composition comprises silicon and geranium.

3. The semiconductor device of claim 2, wherein the first region has a higher semiconductor fin structure density than the second region.

4. The semiconductor device of claim 2, wherein the top surface of the STI region adjacent the second semiconductor fin structure has a U-shaped profile.

5. The semiconductor device of claim 4, further comprising a third semiconductor fin structure disposed in the second region, wherein the third semiconductor fin structure comprises a channel portion comprises silicon, and the third semiconductor fin structure extends from the top surface of the STI region for a third fin height.

6. The semiconductor device of claim 5, wherein the second fin height is greater than the third fin height, and the top surface of the STI region adjacent the third semiconductor fin structure has a planar profile.

7. The semiconductor device of claim 5, wherein the second fin height is substantially the same as the first fin height, and the top surface of the STI region adjacent the third semiconductor fin structure has a U-shaped profile.

8. A semiconductor device, comprising:
a first pattern region comprising:
a first STI region;
first semiconductor fin structures for n-type devices extending from a top surface of the first STI region, wherein the top surface of the first STI region has a planar profile between neighboring first semiconductor fin structures; and
second semiconductor fin structures for p-type devices extending from the top surface of the first STI region, wherein the top surface of the first STI region has a U-shaped profile between neighboring second semiconductor fin structures.

9. The semiconductor device of claim 8, further comprising:
a second pattern region comprising:
a second STI region;
third semiconductor fin structures for n-type devices extending from a top surface of the second STI region, wherein the top surface of the second STI region has a planar profile between neighboring third semiconductor fin structures; and
fourth semiconductor fin structures for p-type devices extending from the top surface of the second STI region, wherein the top surface of the STI region has a planar profile between neighboring fourth semiconductor fin structures.

10. The semiconductor of claim 9, wherein the first semiconductor fin structures have a first fin height extending from the top surface of the first STI region, the third semiconductor fin structures have a second fin height extending from the top surface of the second STI region, and the first fin height is greater than the second fin height.

11. The semiconductor device of claim 10, wherein the second semiconductor fin structure extend from the top surface of the first STI region for the second fin height.

12. The semiconductor device of claim 9, wherein the second pattern region has a higher semiconductor fin density than the first pattern region.

13. The semiconductor device of claim 8, wherein each of the first semiconductor fin structures comprises:
a channel portion comprising silicon and geranium; and
a well portion comprising silicon, wherein the channel portion disposed on the well portion.

14. The semiconductor device of claim 8, wherein the first pattern region further comprises one or more dielectric fin structures disposed adjacent the first semiconductor fin structures.

15. A method for forming a semiconductor device, comprising:
forming first semiconductor fin structures on a first region of a substrate, second semiconductor fin structures on a second region of the substrate, wherein the region has a first pattern density, the second region has a second pattern density, and the first pattern density is greater than the second pattern density;
depositing an isolation layer over the first and second semiconductor fin structures;
planarizing the substrate to expose the first and second semiconductor fin structures;
forming a hard mask over the substrate to expose the second semiconductor fin structures and the isolation layer around the second semiconductor fin structures;
implanting one or more species into exposed portion of the isolation layer;
remove the hard mask; and
etching back the isolation layer to partially expose the first and second semiconductor fin structures, wherein the first semiconductor fin structures have a first fin height extending from a top surface of the isolation layer, the second semiconductor fin structures have a second fin height extending from the top surface of the isolation layer, and the second fin height is greater than the first fin height.

16. The method of claim 15, wherein the forming the first and second semiconductor fin structures comprises:
epitaxially growing a silicon geranium layer over a silicon layer; and
etching through the silicon geranium layer and into the silicon layer to form the first and second semiconductor fin structures.

17. The method of claim 15, wherein implanting one or more species comprises implanting a dopant comprising geranium, argon, nitrogen, arsenic, or carbon.

18. The method of claim 15, wherein the hard mask covers the first pattern region, and areas for n-type devices in the second pattern region.

19. The method of claim 15, wherein the hard mask covers the first pattern region, and exposes the second pattern region.

20. The method of claim 15, further comprising:
depositing a dielectric fin layer over the isolation layer.
